(19) United States
(12) Patent Application Publication
(10) Pub. No.: US 2012/0160807 A1
(43) Pub. Date: Jun. 28, 2012

(54) SYSTEM, METHOD AND APPARATUS FOR REDUCING PLASMA NOISE ON POWER PATH OF ELECTROSTATIC CHUCK

(75) Inventors: Kin-sang Lam, Austin, TX (US); Gary Ray Pierce, JR., Buda, TX (US)

(73) Assignee: SPANSION LLC, Sunnyvale, CA (US)

(21) Appl. No.: 12/979,654

(22) Filed: Dec. 28, 2010

(51) Int. Cl. C23F 1/08; C23F 1/00; C23C 14/34; C23C 14/50; C23C 14/04

(52) U.S. Cl. 216/67; 204/298.15; 204/298.11; 204/192.12; 156/345.48

(57) ABSTRACT

A vacuum plasma system has a table with a table power connector, and a fixture spaced apart from the table for defining a chamber between the table and the fixture. An electrostatic chuck (ESC) is mounted to the table in the chamber. The ESC has a side for supporting a workpiece, and an ESC power connector that electrically couples with the table power connector. A coupling extends between the table and ESC power connectors to provide electrical connection therebetween. A shield surrounds the coupling and portions of the table and ESC power connectors to reduce external fields applied to the coupling.

### BACKGROUND

1. Field of the Disclosure

This disclosure generally relates to vacuum plasma systems and, in particular to an improved system, method and apparatus that reduces plasma noise on the power path of an electrostatic chuck.

2. Description of the Related Art

Some vacuum plasma systems, such as etching and deposition processes, typically use an electrostatic chuck (ESC) to secure a workpiece during processing. Some ESCs are vulnerable to plasma noise generated by plasma strikes along their power paths on the vacuum side of the system. This is due to the high pressures, high DC electrical power requirements, and the relatively large volumes of open spaces in the system. Plasma noise may cause the ESC power to short circuit and reduce the ability of the chuck to hold the workpiece. The short circuits may occur inside the power path cavity, and appear as high current and back side inert gas flow. Accordingly, improvements in vacuum plasma systems would be desirable.

### BRIEF DESCRIPTION OF THE DRAWINGS

So that the manner in which the features and advantages of the embodiments are attained and can be understood in more detail, a more particular description may be had by reference to the embodiments thereof that are illustrated in the appended drawings. However, the drawings illustrate only some embodiments and therefore are not to be considered limiting in scope as there may be other equally effective embodiments.

FIG. 1 is a schematic sectional side view of an embodiment of an evacuated plasma system;

FIG. 2 is an enlarged sectional side view of an embodiment of a portion of an evacuated plasma system;

FIG. 3 is an enlarged sectional side view of another embodiment of a portion of an evacuated plasma system; and

FIGS. 4 and 5 are plots of electrostatic chuck signals over time for unshielded and shielded connectors, respectively.

The use of the same reference symbols in different drawings indicates similar or identical items.

### DETAILED DESCRIPTION

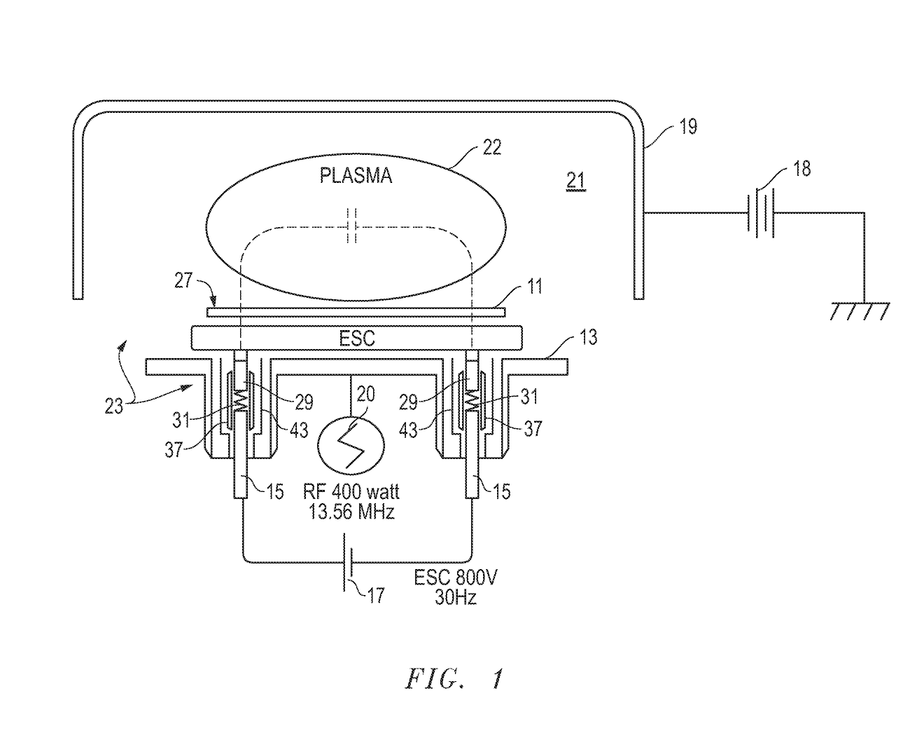

FIGS. 1-5 disclose embodiments of a system, method and apparatus that reduce plasma noise on the power path of an electrostatic chuck. These embodiments are well suited for electrostatic chuck (ESC) designs that use metal rods connected by a spring to provide an electrical path for ESC power. The spring reduces mechanical stress applied to seals on ceramic components. However, the open space inside the spring is large enough to allow plasma strikes inside the power path cavity. This problem may be compounded since it also reduces the cooling capacity of the system and allows some deposited films to agglomerate.

For example, FIG. 1 depicts one embodiment of an evacuated plasma system comprising a sputtering process for film deposition on a workpiece 11. The vacuum plasma system also may readily comprise a plasma etching system for removing material from the workpiece 11. The system may include a table 13 having one or more table power connectors 15 (e.g., two shown). Power 17 may be applied to table power connectors 15 as shown. A fixture 19 is spaced apart from the table for defining a chamber 21 between the table 13 and the fixture 19. The fixture 19 may comprise a target for sputtering, or a radio frequency bias source (e.g., a showerhead) for etching. During processing, the chamber 21 is evacuated and a gas 23, such as an inert gas (e.g., argon), is introduced into the chamber 21. A plasma power source 18, 20 may be used to form plasma 22 in the chamber 21 to ionize gas 23 and process the workpiece 11 as is known to those of ordinary skill in the art.

An ESC 25 is mounted to the table 13 in the chamber 21. The ESC 25 has a side 27 that supports the workpiece 11, and one or more ESC power connectors 29 that electrically couple with the table power connectors 15. In the embodiment shown, side 27 is on top of the ESC 25, and ESC power connectors 29 are on the bottom of the ESC 25.

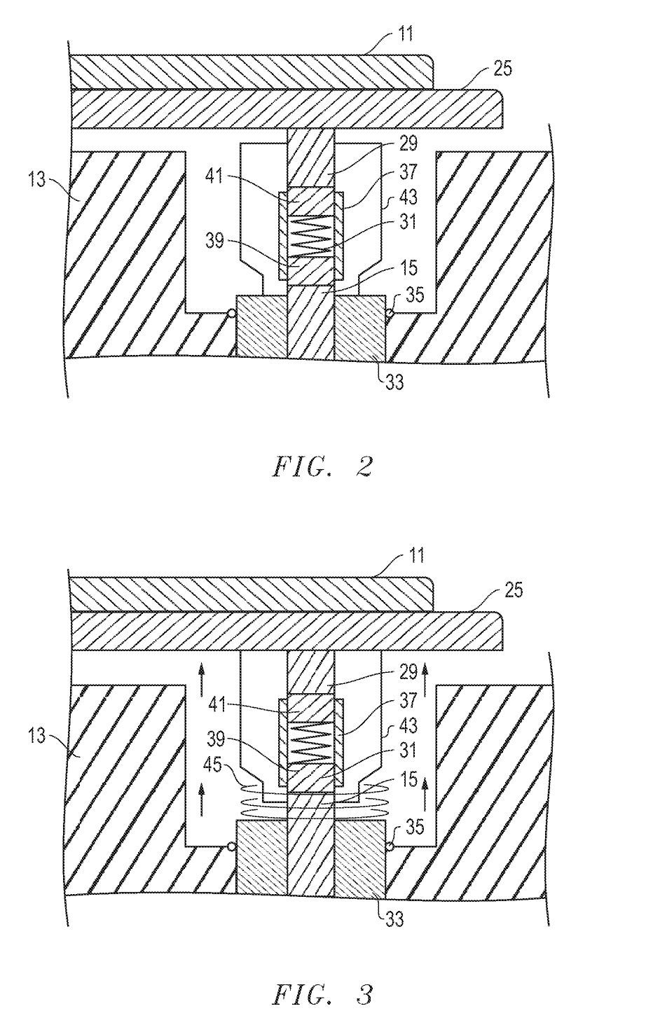

Referring now to FIG. 2, a coupling such as a spring 31 extends axially between the table and ESC power connectors 15, 29. Spring 31 provides electrical connection and axial length flexibility between connectors 15, 29, and defines an electrical path for power 17 (FIG. 1). Each table power connector 15 is mounted in a respective feedthrough 33, such as a ceramic feedthrough. A seal 35 is located between the feedthrough 33 and the table 13. The spring 31 also reduces stress on the seal 35.

In addition, an electrical shield 37 surrounds the spring 31 and portions of the table and ESC power connectors 15, 29. Electrical shield 37 may comprise a Faraday shield that reduces, attenuates or prevents stray fields, such as external electrical or electromagnetic fields from being applied to the power path of the spring. Accordingly, the shield 37 effectively reduces ionization of gas 23 and potential electrical shorts within its interior. In some embodiments, the Faraday shield 37 is a metallic tube supported by the table power connector 15, and the metallic tube 37 closely receives a table pin 39 extending from the table power connector 15 and an ESC pin 41 extending from the ESC power connector 29. The metallic tube 37, table pin 39 and ESC pin 41 are formed from a same material.

In some embodiments, the system further comprises a sleeve 43 (e.g., an insulator such as ceramic) that surrounds the table and ESC power connectors 15, 29, the spring 31 and the electromagnetic shield 37 to electrically isolate them from the table 13. The sleeve 43 may rest on the feedthrough 33 such that it is not biased away from the feedthrough 33 toward the ESC 25. In FIG. 2, an axial space is shown between the top of sleeve 43 and the bottom of ESC 25, such that the sleeve 43 does not contact or seal against the ESC 25. The sleeve 43 may extend vertically closer to the ESC 25 than the electromagnetic shield 37.

In the embodiment of FIG. 3, a second spring 45 is mounted between the feedthrough 33 and the sleeve 43. Second spring 45 biases the sleeve 43 axially upward against the bottom of the ESC 25 to form a seal therebetween. Shield 37 also attenuates any fields that may be generated by second spring 45.

In some embodiments, a method of shielding an evacuated plasma process may comprise placing a workpiece on an electrostatic chuck (ESC) in a vacuum chamber having a table; sending a clamping signal to the ESC through a power path to clamp the workpiece on the ESC; flowing a gas into the vacuum chamber; electromagnetically shielding a portion of the power path from external electric fields; and plasma processing the workpiece. The shield may comprise providing a Faraday shield around an electrical interface between the table and the ESC. In other embodiments, the method further comprises flowing gas from a backside of the ESC to the vacuum chamber, and plasma processing comprises sending a bias power signal to the workpiece to plasma process the workpiece.

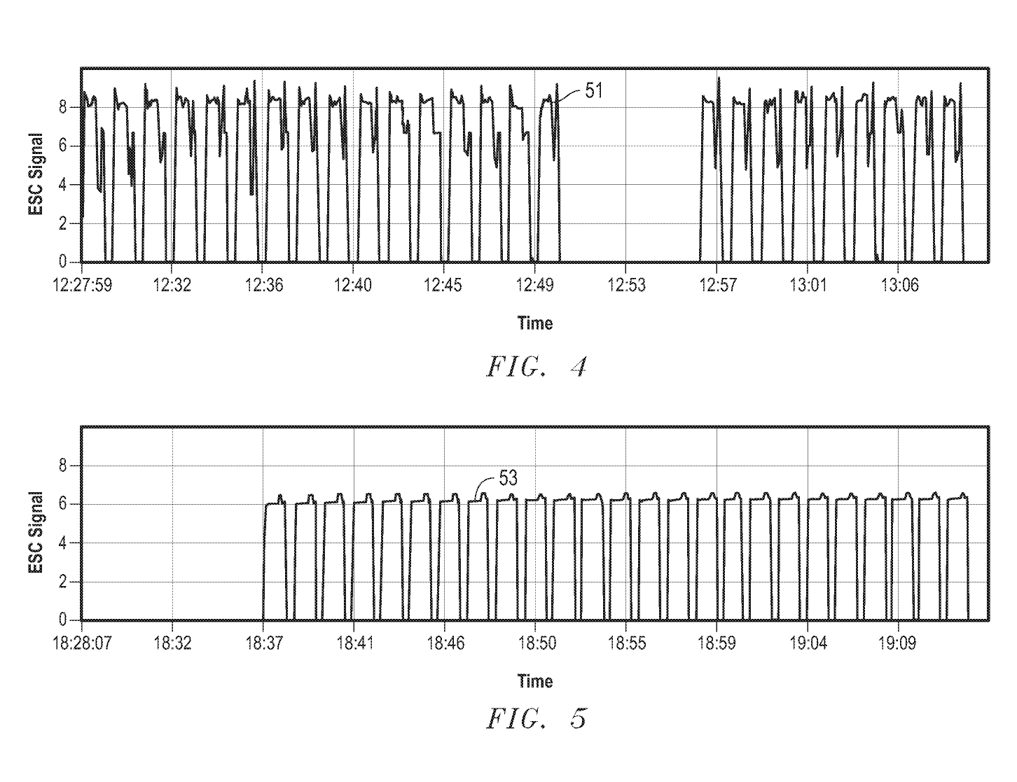

These embodiments have numerous advantages. For example, FIGS. 4 and 5 respectively compare an unshielded power path to a shielded power path as described herein. The vertical axes represent the ESC power signals, and the horizontal axes represent time. FIG. 4 shows that the power peaks 51 of the unshielded connectors are considerably higher than the power peaks 53 (FIG. 5) of the shielded connectors.

This written description uses examples to disclose the embodiments, including the best mode, and also to enable those of ordinary skill in the art to make and use the embodiments. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

Note that not all of the activities described above in the general description or the examples are required, that a portion of a specific activity may not be required, and that one or more further activities may be performed in addition to those described. The order in which activities are listed are not necessarily the order in which they are performed.

In the foregoing specification, the concepts have been described with reference to specific embodiments. However, one of ordinary skill in the art appreciates that various modifications and changes can be made without departing from the scope of the embodiments as set forth in the claims below. Accordingly, the specification and figures are to be regarded in an illustrative rather than a restrictive sense, and all such modifications are intended to be included within the scope of the embodiments.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of scope. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. A vacuum plasma system, comprising:
a table having a table power connector;
a fixture spaced apart from the table for defining a chamber between the table and the fixture;
an electrostatic chuck (ESC) mounted to the table in the chamber, the ESC is adapted to support a workpiece and has an ESC power connector that electrically couples with the table power connector;
a coupling extending between the table and ESC power connectors to provide electrical connection therebetween; and
a shield surrounding the coupling and portions of the table and ESC power connectors to reduce external fields applied to the coupling.

2. A system according to claim 1, wherein the shield is a Faraday shield.

3. A system according to claim 2, wherein the Faraday shield is a metallic tube supported by the table power connector, and the metallic tube closely receives a table pin extending from the table power connector and an ESC pin extending from the ESC power connector.

4. A system according to claim 3, wherein the metallic tube, table pin and ESC pin are formed from a same material.

5. A system according to claim 1, wherein the vacuum plasma system is plasma etching system for removing material from the workpiece and the fixture is a radio frequency bias source.

6. A system according to claim 1, wherein the vacuum plasma system is a sputtering process system for film deposition on the workpiece and the fixture is a target.

7. A system according to claim 1, further comprising an insulative sleeve surrounding the table and ESC power connectors, the coupling and the shield to electrically isolate them from the table.

8. A system according to claim 7, wherein the insulative sleeve has an axis and is axially spaced apart from the ESC such that the ceramic sleeve does not contact or seal against the ESC.

9. A system according to claim 8, wherein the table power connector is mounted in a feedthrough, and the insulative sleeve rests on the feedthrough and is not biased away from the feedthrough toward the ESC.

10. A system according to claim 9, further comprising a seal between the feedthrough and the table, and the coupling reduces stress on the seal.

11. A system according to claim 7, wherein the table power connector is mounted in a feedthrough, and the insulative sleeve rests on the feedthrough; and further comprising:
a second spring mounted between the feedthrough and the insulative sleeve for biasing an insulative sleeve upward against the ESC to form a seal therebetween.

12. A system according to claim 7, wherein the insulative sleeve extends vertically closer to the ESC than the shield.

13. A vacuum plasma system, comprising:
a table having a table power connector;
a fixture spaced apart from the table for defining a chamber between the table and the fixture;
an electrostatic chuck (ESC) mounted to the table in the chamber, the ESC is adapted to support a workpiece and has an ESC power connector that electrically couples with the table power connector;
a spring extending between the table and ESC power connectors to provide electrical connection therebetween and define a power path;
a Faraday shield surrounding the spring and portions of the table and ESC power connectors to reduce external fields applied to the spring; and
an insulative sleeve surrounding the table and ESC power connectors, the spring and the Faraday shield to electrically isolate them from the table.

14. A system according to claim 13, wherein the Faraday shield is a metallic tube supported by the table power connector, the metallic tube closely receives a table pin extending from the table power connector and an ESC pin extending from the ESC power connector, and the metallic tube, table pin and ESC pin are formed from a same material.

15. A system according to claim 13, wherein the vacuum plasma system is plasma etching system for removing material from the workpiece and the fixture is a radio frequency bias source.

16. A system according to claim 13, wherein the vacuum plasma system is a sputtering process system for film deposition on the workpiece and the fixture is a target.

17. A system according to claim 13, wherein the insulative sleeve has an axis and is axially spaced apart from the ESC such that the ceramic sleeve does not contact or seal against the ESC.

18. A system according to claim 13, wherein the table power connector is mounted in a feedthrough, the insulative sleeve rests on the feedthrough and is not biased away from the feedthrough toward the ESC, and further comprising a seal between the feedthrough and the table, and the spring reduces stress on the seal.

19. A system according to claim 13, wherein the table power connector is mounted in a feedthrough, and the insulative sleeve rests on the feedthrough; and further comprising:
a second spring mounted between the feedthrough and the insulative sleeve for biasing the insulative sleeve upward against the ESC to form a seal therebetween.

20. A method of shielding in a vacuum plasma system, comprising:
placing a workpiece on an electrostatic chuck (ESC) in a vacuum chamber having a table;
sending a clamping signal to the ESC through a power path to clamp the workpiece on the ESC;
flowing a gas into the vacuum chamber;
shielding a portion of the power path from external electric fields; and
plasma processing the workpiece.

21. A method according to claim 20, wherein shielding comprises providing a Faraday shield around an electrical interface between the table and the ESC.

22. A method according to claim 20, further comprising flowing gas from a backside of the ESC to the vacuum chamber, and plasma processing comprises sending a bias power signal to the workpiece to plasma process the workpiece.
